(19) United States
(12) Patent Application Publication
(10) Pub. No.: US 2014/0203404 A1
(43) Pub. Date: Jul. 24, 2014

(54) SPIRAL METAL-ON-METAL (SMOM) CAPACITORS, AND RELATED SYSTEMS AND METHODS

(71) Applicant: QUALCOMM INCORPORATED, San Diego, CA (US)

(72) Inventors: Jihong Choi, San Diego, CA (US); John J. Zhu, San Diego, CA (US); PR Chidambaram, San Diego, CA (US); Bin Yang, San Diego, CA (US); Lixin Ge, San Diego, CA (US)

(73) Assignee: QUALCOMM INCORPORATED, San Diego, CA (US)

(21) Appl. No.: 13/745,962

(22) Filed: Jan. 21, 2013

(51) Int. Cl. H01L 49/02

(52) U.S. Cl. CPC H01L 28/87
USPC 257/534; 438/399

(57) ABSTRACT

Spiral metal-on-metal (MoM or SMoM) capacitors and related systems and methods of forming MoM capacitors are disclosed. In one embodiment, a MoM capacitor disposed in a semiconductor die is disclosed. The MoM capacitor comprises a first electrode coupled to a first trace. The first trace is coiled in a first inwardly spiraling pattern and comprised of first parallel trace segments. The MoM capacitor also comprises a second electrode coupled to a second trace. The second trace is coiled in the first inwardly spiraling pattern and comprised of second parallel trace segments interdisposed between the first parallel trace segments. Reduced variations in the capacitance allow circuit designers to build circuits with tighter tolerances and generally improve circuit reliability.

### BACKGROUND

I. Field of the Disclosure

The technology of the disclosure relates generally to metal-on-metal (MoM) capacitors.

II. Background

Mobile communication devices have become common in current society. The prevalence of these mobile devices is driven in part by the many functions that are now enabled on such devices. Demand for such functions increases processing capability requirements and generates a need for more powerful batteries. Within the limited space of the housing of the mobile communication device, batteries compete with the processing circuitry. These and other factors contribute to a continued miniaturization of components within the circuitry.

Miniaturization of the components impacts all aspects of the processing circuitry including the transistors and other reactive elements in the processing circuitry, such as capacitors. One miniaturization technique involves moving some reactive elements from the printed circuit board into the integrated circuitry. One technique for moving reactive elements into the integrated circuitry involves creating metal-on-metal (MoM) capacitors during back end of line (BEOL) integrated circuit fabrication.

Current BEOL MoM capacitors use a two element interdigitated structure which has proven acceptable for devices in which the space between electrodes is forty nanometers (40 nm) or greater. Such capacitors are created using masks and metal deposition processes. Currently known lithography processes allow a space of approximately a small as forty (40) nm between electrodes while using a single mask process. However, miniaturization-focused designers are now trying to create circuits with electrodes with even smaller spaces, such as, for example, thirty-two (32) nm or smaller. When the space between conductive elements is this small, it is currently not possible for a single mask to provide both elements of the interdigitated structure. As a result, for these small line spaces, current processes use two masks to create the interdigitated structure. In such processes, a substrate is provided and the first mask is positioned thereon. A metal deposition technique is used to generate the first conductive element. The first mask is then removed and a second mask is applied that covers the just created first conductive element. A metal deposition technique is used to generate the second conductive element. Unfortunately, the use of two masks may result in misalignment of the second conductive element relative to the first conductive element and corresponding variations in the resulting capacitive devices. While some process variations are tolerable, current process variations exceed design parameters and a better process is needed.

### SUMMARY OF THE DETAILED DESCRIPTION

Embodiments disclosed in the detailed description include spiral metal-on-metal (MoM or SMoM) capacitors. Related systems and methods of forming MoM capacitors are also disclosed. In particular, the present disclosure provides a. MoM capacitor formed by inwardly spiraling conductive traces which reduces variations in the capacitances of the resulting device as compared to the interdigitated structures. Reduced variations in the capacitance allow circuit designers to build circuits with tighter tolerances, and generally improve circuit reliability.

In this regard in one embodiment a multilayer MoM capacitor disposed in a semiconductor die is disclosed. The multilayer MoM capacitor comprises a first layer that comprises a first electrode of the MoM capacitor coupled to a first trace, the first trace coiled in a first inwardly spiraling pattern and comprised of first parallel trace segments. The first layer also comprises a second electrode of the MoM capacitor coupled to a second trace, the second trace coiled inside the first inwardly spiraling pattern and comprised of second parallel trace segments interdisposed between the first parallel trace segments. The multilayer MoM also comprises a second layer that comprises the second electrode of the MoM capacitor coupled to a third trace, the third trace coiled in a second inwardly spiraling pattern. The second layer also comprises the first electrode of the MoM capacitor coupled to a fourth trace, the fourth trace coiled inside the second inwardly spiraling pattern.

In another embodiment, a muitilayer MoM capacitor disposed in a semiconductor die is disclosed. The multilayer MoM capacitor comprises a first layer that comprises a first electrode of the MoM capacitor coupled to a first conducting means, the first conducting means coiled in a first inwardly spiraling pattern and comprised of first parallel trace segments. The first layer also comprises a second electrode of the MoM capacitor coupled to a second conducting means, the second conducting means coiled inside the first inwardly spiraling pattern and comprised of second parallel trace segments interdisposed between the first parallel trace segments. The multilayer MoM capacitor also comprises a second layer that comprises the second electrode of the MoM capacitor coupled to a third conducting means, the third conducting means coiled in a second inwardly spiraling pattern. The second layer also comprises the first electrode of the MoM capacitor coupled to a fourth conducting means, the fourth conducting means coiled inside the second inwardly spiraling pattern.

In another embodiment, a circuit in a semiconductor die comprising a multilayer MoM capacitor is disclosed. The multilayer MoM capacitor comprises a first layer that comprises a first electrode of the MoM capacitor coupled to a first trace, the first trace coiled in a first inwardly spiraling pattern and comprised of first parallel trace segments. The first layer also comprises a second electrode of the MoM capacitor coupled to a second trace, the second trace coiled inside the first inwardly spiraling pattern and comprised of second parallel trace segments interdisposed between the first parallel trace segments. The multilayer MoM also comprises a second layer that comprises the second electrode of the MoM capacitor coupled to a third trace, the third trace coiled in a second inwardly spiraling pattern. The second layer also comprises the first electrode of the MoM capacitor coupled to a fourth trace, the fourth trace coiled inside the second inwardly spiraling pattern.

In another embodiment, a method of forming a MoM capacitor is disclosed. The method comprises providing a first mask for a semiconductor die. The first mask delimits a first inwardly spiraling pattern. The method also comprises positioning the first mask on a top layer of the semiconductor die. The method also comprises depositing a first metal on the first mask to form a first electrode and a first trace of the MoM capacitor. The first trace is formed in the inwardly spiraling pattern comprised of first parallel trace segments. The method also comprises providing a second mask for the semiconductor die. The second mask delimits a second inwardly spiraling pattern. The method also comprises positioning the second mask on the top layer of the semiconductor die. The method also comprises depositing a second metal on the second mask to form a second electrode and a second trace of the MoM capacitor. The second trace is formed coiled in the first inwardly spiraling pattern and comprised of second parallel trace segments interdisposed between the first parallel trace segments.

### BRIEF DESCRIPTION OF THE FIGURES

FIG. 1A is top plan view of a partially constructed conventional interdigitated metal-on-metal (MoM) capacitor;

FIG. 1B is a top plan view of the constructed conventional interdigitated MoM capacitor of FIG. 1A;

FIGS. 1C-1E are exploded views of exemplary misalignments that may occur in the interdigitated structure of FIG. 1B;

FIG. 1F is a graph of an exemplary capacitance deviation that may result from misalignments;

FIG. 2 illustrates a top plan view of an exemplary spiral MoM capacitor according to an embodiment of the present disclosure;

FIG. 3 illustrates a flow chart of an exemplary manufacturing process to create the spiral MoM capacitor of FIG. 2;

FIG. 4A illustrates a top plan view of an exemplary partially constructed spiral MoM capacitor;

FIG. 4B illustrates a top plan view of an exemplary completed spiral MoM capacitor with the traces differentiated to improve contrast therebetween;

FIG. 5 illustrates an exemplary graph contrasting the capacitance deviation between spiral MoM capacitors and interdigitated MoM capacitors;

FIG. 6 illustrates an exemplary graph contrasting the maximum capacitance deviation between spiral MoM capacitors and interdigitated MoM capacitors;

FIG. 7 illustrates an exemplary graph contrasting the capacitive density between spiral MoM capacitors and interdigitated MoM capacitors;

FIGS. 8 and 9 illustrate alternate embodiment spiral MoM capacitors;

FIGS. 10-12B illustrate an exemplary embodiment of a multilayer spiral MoM capacitor with layers rotated relative to adjacent layers; and

FIG. 13 is a block diagram of an exemplary processor-based system that can include the spiral MoM capacitor of FIG. 2, 8, 9, or 10-12B.

### DETAILED DESCRIPTION

With reference now to the drawing figures, several exemplary embodiments of the present disclosure are described. The word “exemplary” is used herein to mean “serving as an example, instance, or illustration.” Any embodiment described herein as “exemplary” is not necessarily to be construed as preferred or advantageous over other embodiments.

Embodiments disclosed in the detailed description include spiral metal-on-metal (MoM or SMoM) capacitors. Related systems and methods of forming MoM capacitors are also disclosed. In particular, the present disclosure provides a capacitor formed by inwardly spiraling conductive traces which reduces variations in the capacitances of the resulting device as compared to the interdigitated structures.

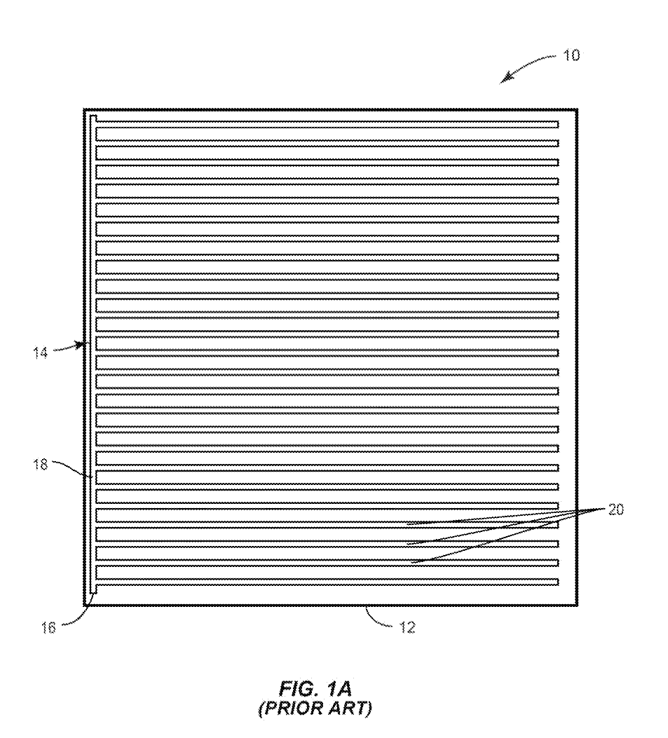

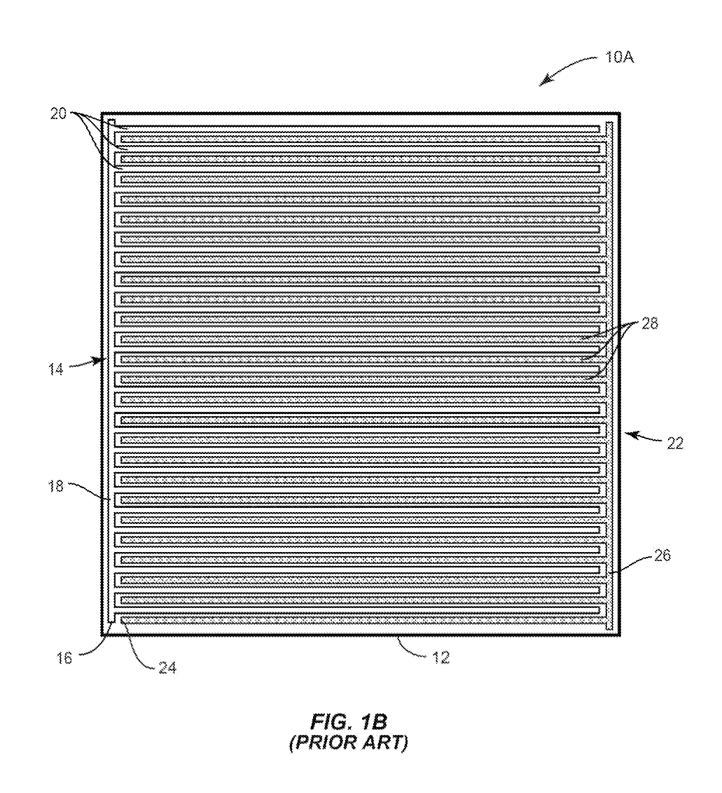

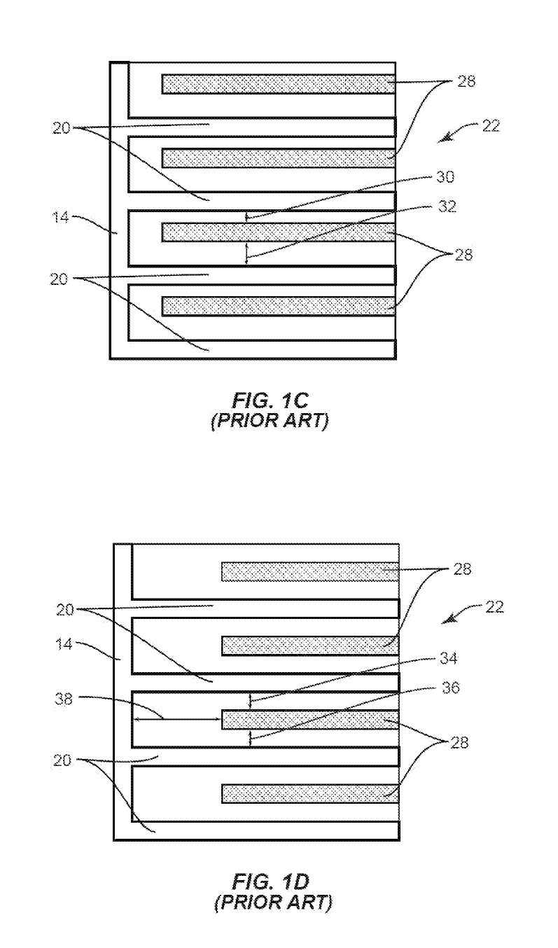

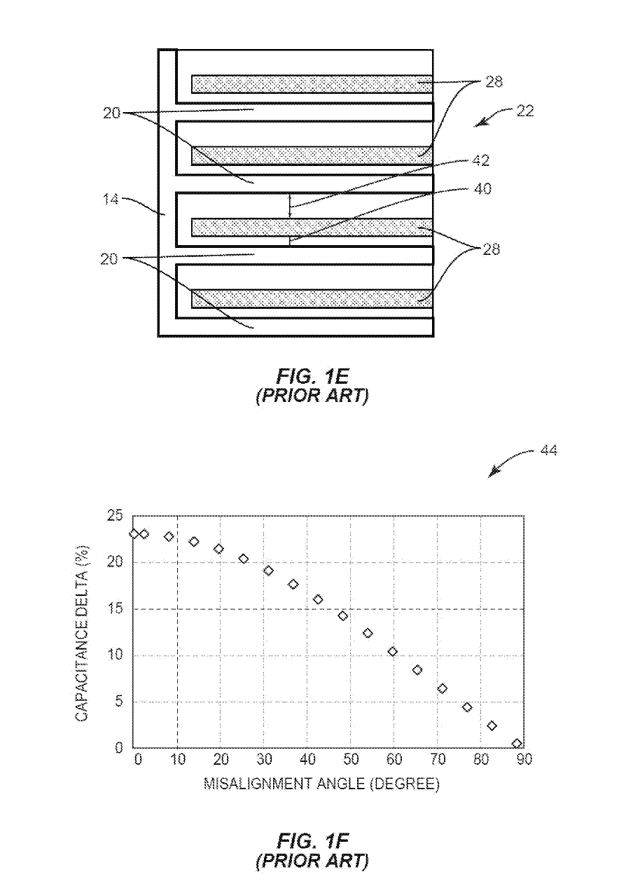

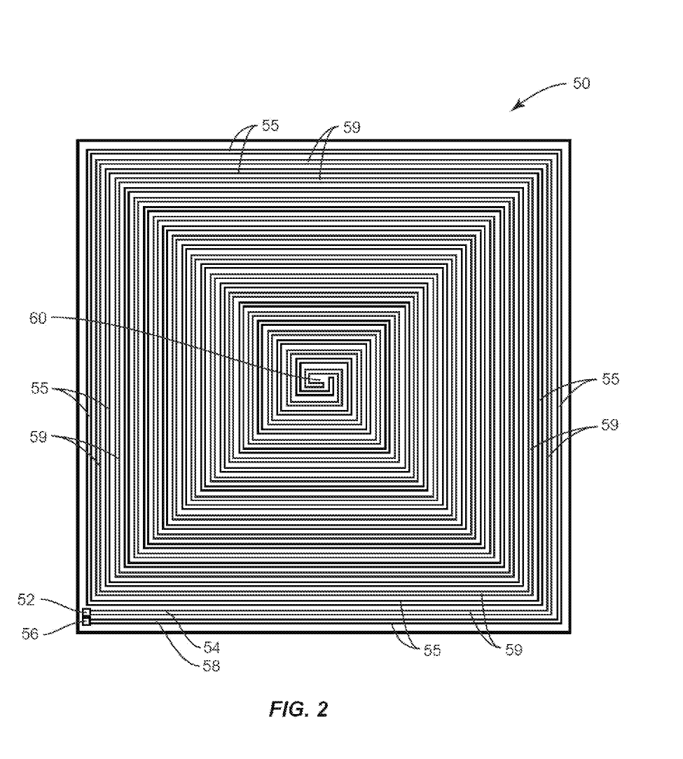

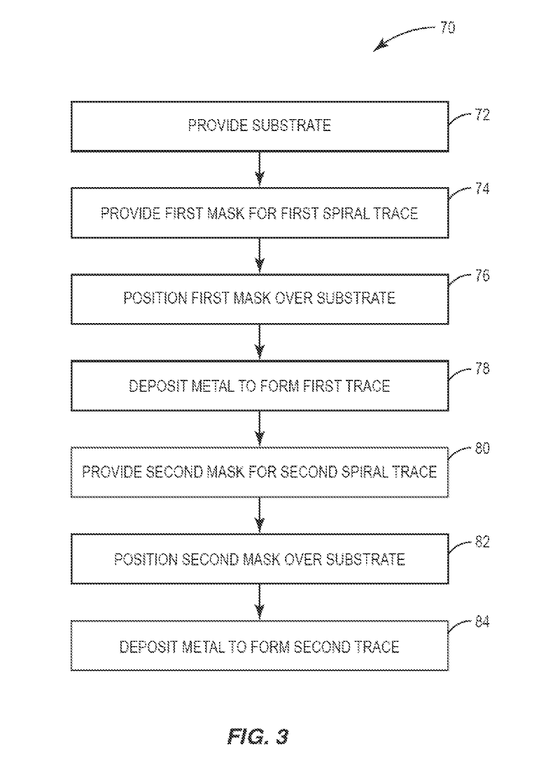

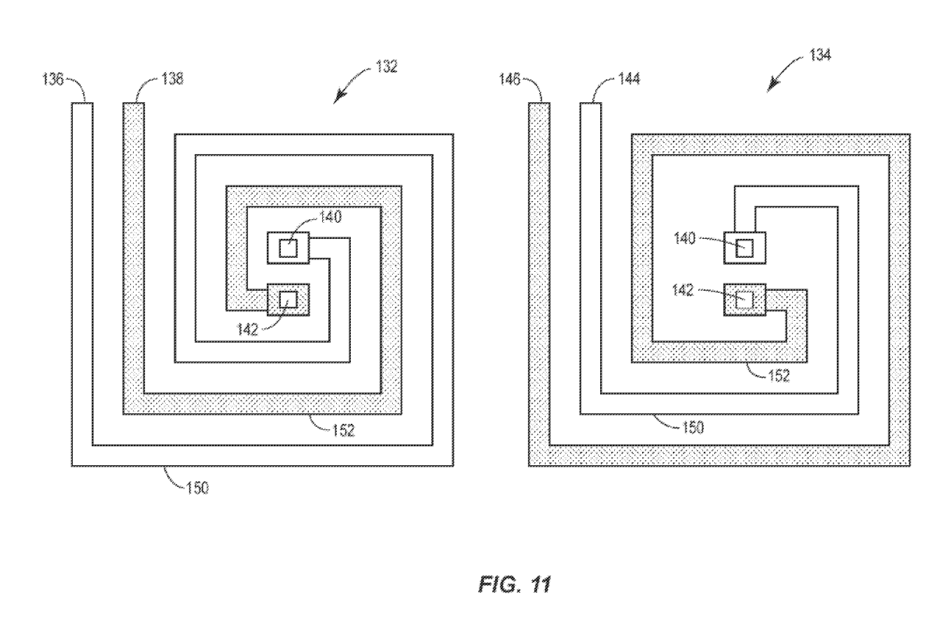

Before discussing embodiments of the SMoM capacitors of the present disclosure starting at FIG. 2, a discussion of conventional interdigitated MoM structures and the deficiencies thereof is provided with reference to FIGS. 1A-1F. Discussion of exemplary embodiments of the present disclosure begins below with reference to FIG. 2. A multilayer embodiment is provided with reference to FIGS. 10-12B.

In this regard, FIG. 1A illustrates a partially constructed conventional interdigitated MoM capacitor 10 having a substrate 12 and a first interdigitated structure 14. The first interdigitated structure 14 includes a first electrode 16 and a first electrical trace 18 having fingers 20. In practice, the first interdigitated structure 14 is formed on the substrate 12 through the use of a first mask (not shown) and a metal deposition process (e.g., sputtering, vapor deposition, or the like). In particularly contemplated embodiments, the first electrical trace 18 may have a line width of approximately thirty-two nanometers (32 nm).

A completed conventional interdigitated MoM capacitor 10A is illustrated in FIG. 1B. The interdigitated MoM capacitor 10A builds on the substrate 12 and the first interdigitated structure 14 by adding a second interdigitated structure 22 having a second electrode 24 and a second electrical trace 26 having fingers 28. Note that because of the fingers 20, 28, the interdigitated MoM capacitor 10A is sometimes referred to as a Finger Metal-on-Metal (FMoM). The second interdigitated structure 22 is formed on the substrate 12 through the use of a second mask (not shown) and a metal deposition process as is well understood. As with the first electrical trace 18, the second electrical trace 26 may have a line width of approximately thirty-two nanometers (32 nm). By design, the first electrical trace 18 and the second electrical trace 26 may have thirty-two (32) nm between each other. It is the narrowness of the electrical traces 18 and 26 and the narrowness of the gap therebetween that necessitate the use of the two masks in fabrication. That is, if the gap is less than approximately forty (40) nm, a two mask process is needed using conventional technology. Thicker line widths and thicker gaps allow a single mask to be used as is well understood.

The problem with a two mask approach and an interdigitated structure in FIGS. 1A and 1B is the second mask may be misaligned relative to the first interdigitated structure resulting in misalignment of the two interdigitated structures. Such misalignment results in variations in the capacitance of the resulting device, which in turn may make the resulting device unsuitable for its intended use (e.g., if a capacitor with a 10 pF capacitance is needed, the variance may make a device with only 1 pF, which may not operate as intended). Examples of such misalignment are provided in FIGS. 1C through 1E. In FIG. 1C, the second interdigitated structure 22 is misaligned “up” and “to the right” relative to a correct alignment. This disposes the fingers 20 into close proximity with fingers 28 at point 30 and widens the gap at point 32. With reference to FIG. 1D, the second interdigitated structure 22 is misaligned just “to the right” relative to a correct alignment. Thus, the gaps 34 and 36 between the fingers 20 and 28 are equal, although the gap 38 is wider than designed. With reference to FIG. 1E, the second interdigitated structure 22 is misaligned “down” and “to the left” relative to a correct alignment. Thus, the gap 42 is wider than designed and the gap 40 is smaller than designed. Such changes in the gaps between the fingers 20, 28 change the geometries of the interdigitated structures 14, 22, which in turn changes the capacitance provided by the capacitor 10A. While three possible misalignments are illustrated, it is to be understood that other misalignments can and do occur during the manufacturing process.

In this regard, FIG. 1F provides a graph 44 that shows the degree of change in capacitance as a function of the angle of misalignment. A low misalignment angle corresponds to a large vertical misalignment, but small horizontal misalignment. As the angle increases, the horizontal component increases and the vertical component decreases until at ninety (90) degrees, there is only a horizontal misalignment (e.g., such as shown in FIG. 1D). As is readily seen, variations in the capacitance of almost 25% are possible. Such variations may exceed design tolerances.

The present disclosure addresses the problems of misalignment by providing a SMoM capacitor, such as exemplary SMoM capacitor 50 illustrated in FIG. 2. In this regard. SMoM capacitor 50 includes a first electrode 52 electrically coupled to a first trace 54 and a second electrode 56 electrically coupled to a second trace 5$. As used herein, the first and second electrodes are sometimes referred to as means for electrical connection. Each trace 54, 58 is spirally wound towards a center point 60. The first trace 54 is formed, in one embodiment (illustrated) from rectilinear or substantially rectilinear, first parallel trace segments 55. Likewise, the second trace 58 is formed from second parallel trace segments 59. The traces 54, 58 are concentrically coiled one inside the other such that the second parallel trace segments 59 are interdisposed between the first parallel trace segments 55. As used herein, the first and second traces are sometimes referred to as conducting means. While the SMoM capacitor 50 uses two masks in its creation as explained below, the variations in the capacitance seen in the interdigitated structure are avoided. While some variations do still exist, the amount of variation is more tightly constrained and easier to accommodate within design parameters.

In an exemplary embodiment, the second parallel trace segments 59 are substantially centered between the first parallel trace segments 55. In an exemplary embodiment, the line width of the traces 54, 58 is approximately thirty-two nanometers (32 nm) and the gap between traces is also approximately thirty-two (32) nm. While line widths of approximately thirty-two (32) nm are specifically contemplated, the present disclosure is not so limited. Other exemplary embodiments include line widths of less than forty (40) nm or between approximately twenty and forty (20-40) nm. It should be appreciated that if the gap or the spacing between traces is less than approximately forty (40) nm, a two mask process is required. In an exemplary embodiment, the spacing is less than forty (40) nm and accordingly, a high density capacitor is created having a density greater than previously possible for a given footprint.

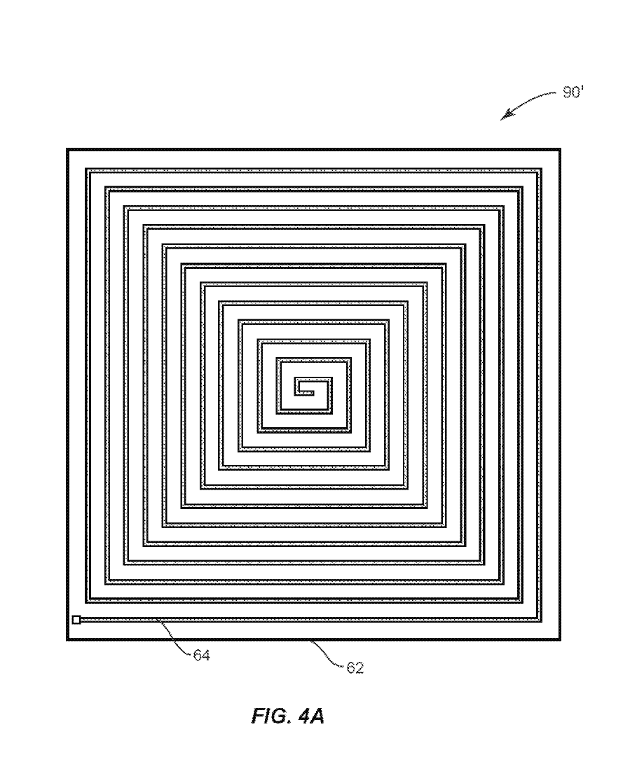

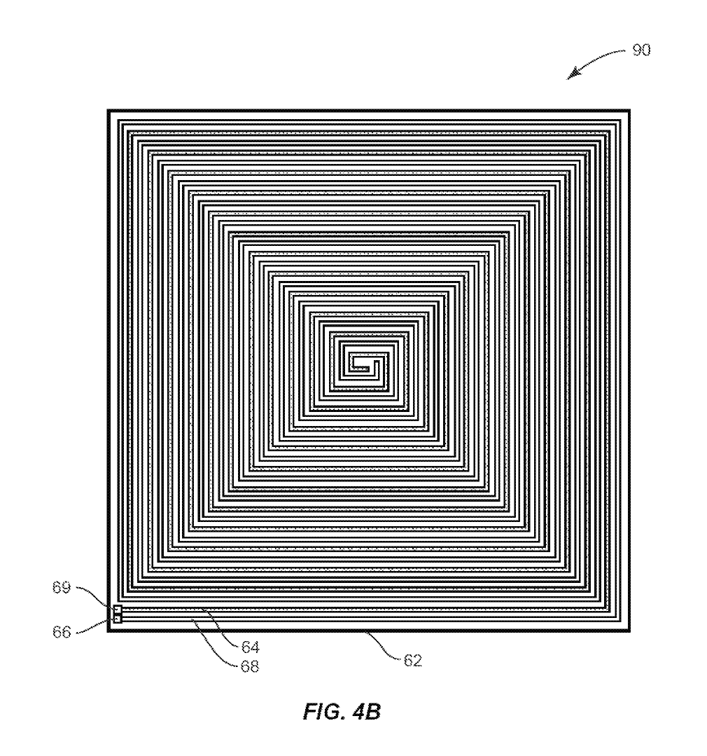

A two mask process may be used to create the small line widths and small gaps during a back end of the line (BEOL) process. A flow chart of an exemplary two mask process 70 is provided in FIG. 3 with exemplary outputs from the process illustrated in FIGS. 4A and 4B. The process begins by providing a semiconductor die having a substrate (block 72) (see substrate 62 in FIGS. 4A, 4B). A first mask (not illustrated) delimiting a first inwardly spiraling pattern for creating a first spiral trace is provided (block 74). The first mask is positioned over the substrate 62 (block 76). As is understood, the first mask is positioned over a top layer of the substrate. A conductive metal is deposited on the substrate 62 through the first mask, thereby forming the first spiral trace (block 78) (see first trace 64 in FIG. 4A) and a first electrode 66.

A second mask (not illustrated) delimiting a second inwardly spiraling pattern for creating the second spiral trace is provided (block 80). The second mask is positioned over the substrate 62 (block 82). A conductive metal is deposited on the substrate 62 through the second mask, thereby forming the second spiral trace (block 84) (see second trace 68 in FIG. 4B) and a second electrode 69. Collectively, the substrate 62, the first trace 64, and the second trace 68 with the electrodes 66 and 69 form a SMoM capacitor 90 (FIG. 4B). The partially assembled SMoM capacitor of FIG. 4A is denoted 90″. In an exemplary embodiment, the metal of the first trace 64 and the second trace 68 are the same type of metal and are conductive such as copper, gold, silver, platinum, aluminum or the like.

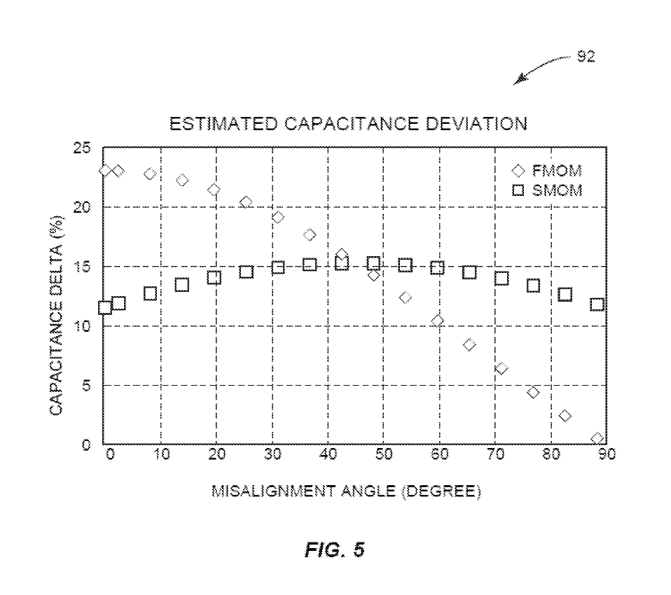

While the use of the two masks is designed to allow the interdisposed trace segments to be positioned substantially centered relative to one another, as with the interdigitated or FMoM capacitors, use of the two masks may introduce misalignment between the two masks and may result in capacitance variation. The final capacitance (C_{f}) is the sum of the target capacitance (C_{T}), single mask process variation (ΔG_{c}), and double mask process variation (ΔG_{td}). This may be conceptualized through the following formula: C_{f}=C_{T}+ΔG+ΔG_{td}. As noted with respect to FIG. 1F, in an FMoM capacitor structure, the capacitance deviation fluctuates wildly depending on the angle of misalignment. In contrast, as illustrated by the graph 92 in FIG. 5, the capacitance deviation is tightly constrained for a SMoM capacitor. That is, preliminary testing and simulation reflects that the capacitance deviation varies from about 11% to about 15%. It is much easier to design circuits with this degree of tolerance than with designs that must accommodate variations of greater than 20%, such as may occur with a FMoM capacitor.

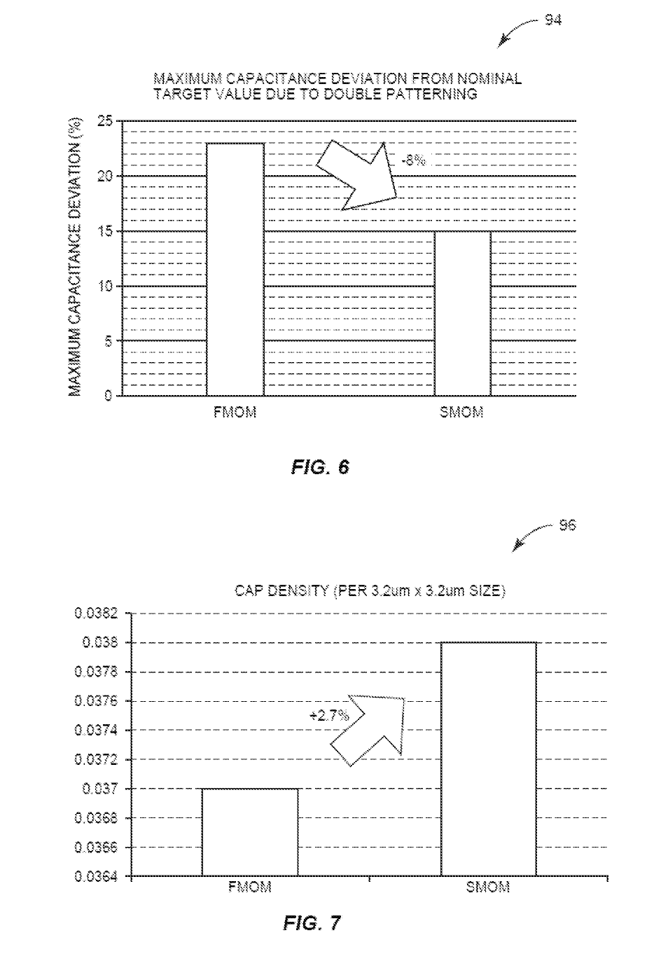

In this regard, FIG. 6 illustrates through graph 94 how much better the SMoM capacitor design is than the FMoM capacitor design. That is, the deviation for an exemplary SMoM is 15% while the deviation for the exemplary FMoM is 23%, meaning that the SMoM is an 8% improvement over the FMoM. Empirical testing confirms this improvement, although it is possible that better or worse improvement may be achieved.

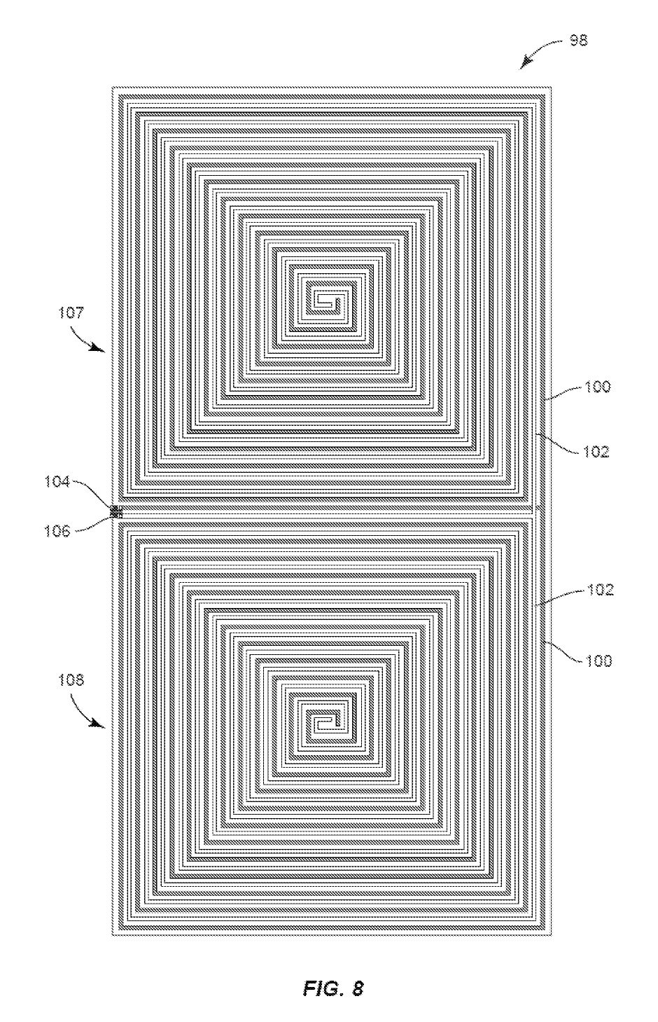

In addition, in FIG. 7 the SMoM capacitor design provides a greater capacitive density for a given size capacitor as illustrated by exemplary graph 96. Testing and simulations indicate that the SMoM capacitor design improves capacitive density by 2.7%. As noted above, design constraints push for ever smaller components, so greater capacitive density allows smaller capacitors to provide the same amount of capacitance and meet design requirements.

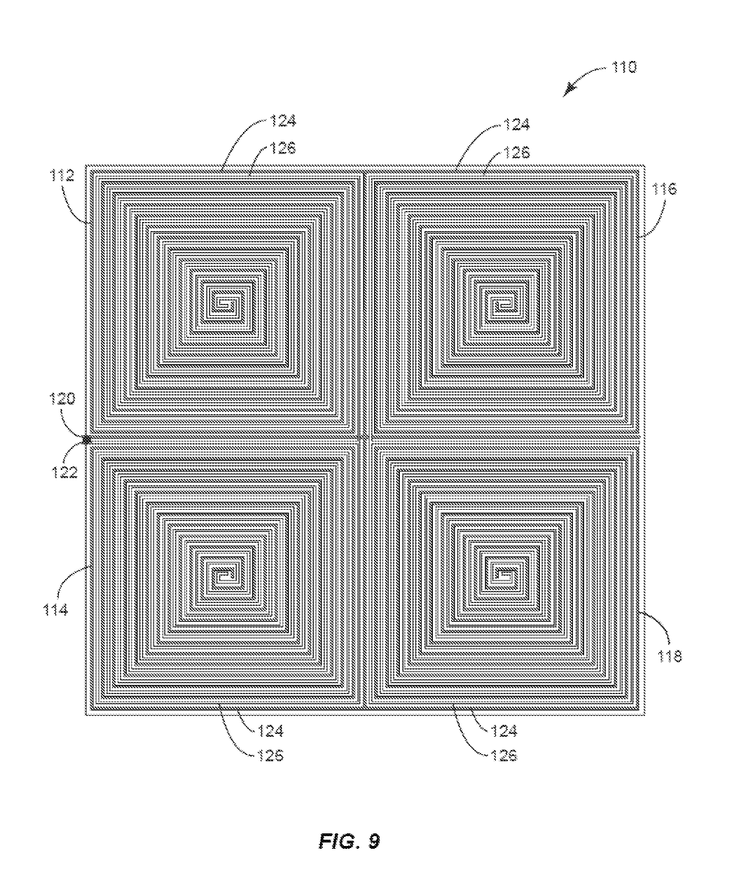

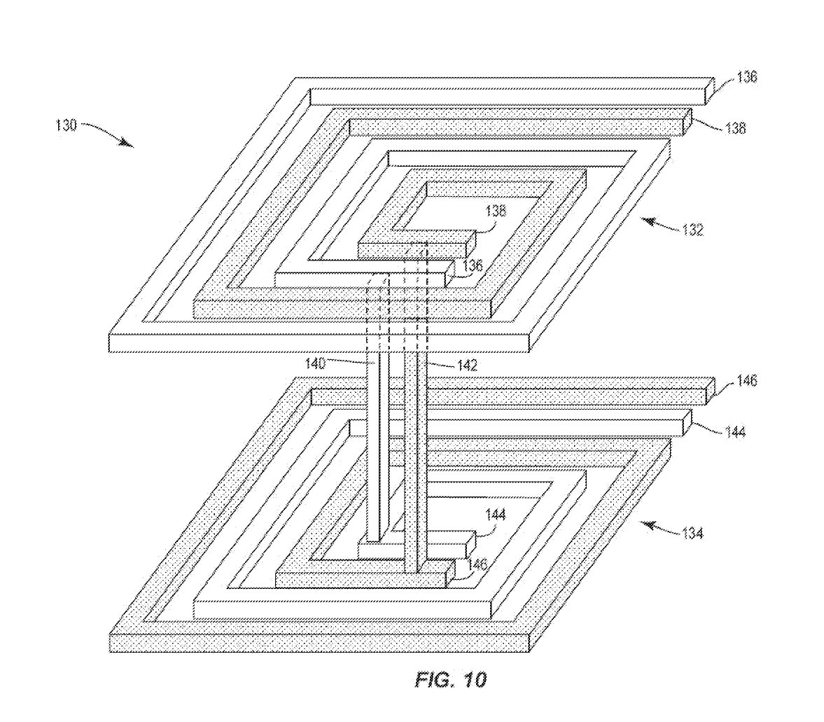

While the present disclosure has focused on a single pair of spiral traces in a single spiral coil, the present disclosure is not so limited. Two alternate embodiments are illustrated in FIGS. 8 and 9. Specifically, FIG. 8 illustrates a double SMoM capacitor 98. While illustrated as a vertical configuration, it should be appreciated that a horizontal configuration is also possible. Double SMoM capacitor 98 still only has two spiral traces 100, 102 and two electrodes 104, 106. The spiral traces 100, 102 form a first spiral arrangement 107 and a second spiral arrangement 108. The second spiral arrangement 108 increases the size of the SMoM capacitor 98 and thus increases the capacitance. The change in the geometry of the capacitor relative to a single coil allows for different design criteria to be met and is not necessarily superior or inferior to a single coil design. Alternatively and not illustrated, the second spiral arrangement 108 may be a different capacitor than the first spiral arrangement 107.

With reference to FIG. 9, a second alternate embodiment is a four-fold or quad SMoM capacitor 110. The quad SMoM capacitor 110 includes first through fourth spiral arrangements 112, 114, 116, and 118, which share first electrode 120, second electrode 122, first trace 124 and second trace 126. Again, the change in geometry relative to a single coil allows for different design criteria to be met and is not necessarily superior or inferior to a single coil design. Alternatively, and not illustrated, the quad spiral arrangements may be different capacitors or there may be two capacitors (e.g., 112, 114 form one capacitor and 116, 118 form a second) or three capacitors (e.g., 112, 114, and 116 form one capacitor and 118 forms the second). While the examples of the previous sentence suggest specific groupings, alternate groupings are also possible as needed or desired.

While FIGS. 8 and 9 illustrate two specific alternate embodiments, should be appreciated that other N×M matrix arrays of spiral arrangements may be provided to meet specific design criteria. The variously sized matrices may allow different ones of the spiral arrangements to be grouped as a collective capacitor or used as a single arrangement as needed or desired by design factors. While the embodiments of FIGS. 8 and 9 allow for greater capacitance, such increased capacitance is provided at the expense of a device with a larger footprint. Such larger footprints conflict with the miniaturization pressures explained above.

In this regard, a three-dimensional capacitor may be provided to increase the capacitance of the structure while preserving the smaller footprint of the SMoM 90. One such three-dimensional or multilayer SMoM capacitor 130 is illustrated in FIGS. 10-12B. With reference to FIG. 10, a perspective view of multilayer spiral MoM capacitor 130 is illustrated. The spiral MoM capacitor 130 includes a first layer 132 and a second layer 134. The first layer 132 includes a first trace 136 and a second trace 138, which spiral inwardly as previously explained with respect the embodiment of FIGS. 2 and 4. Vias 140 and 142 couple the first layer 132 to the second layer 134 and to corresponding traces 144 and 146. Note that first trace 136 is coupled to the corresponding trace 144 and the second trace 138 is coupled to the corresponding trace 146. By design, the first, trace 136 is on the outside of the spiral on the first layer 132 and corresponding trace 144 is on the inside of the spiral on the second layer 134. Likewise, the second trace 138 is on the inside of the spiral on the first layer 132 and on the outside of the spiral on the second layer 134. Put another way, elements of the second layer 134, the corresponding trace 144 that is electrically coupled to the first trace 136 is inwardly positioned relative to corresponding trace 146 that is electrically coupled to the second trace 138.

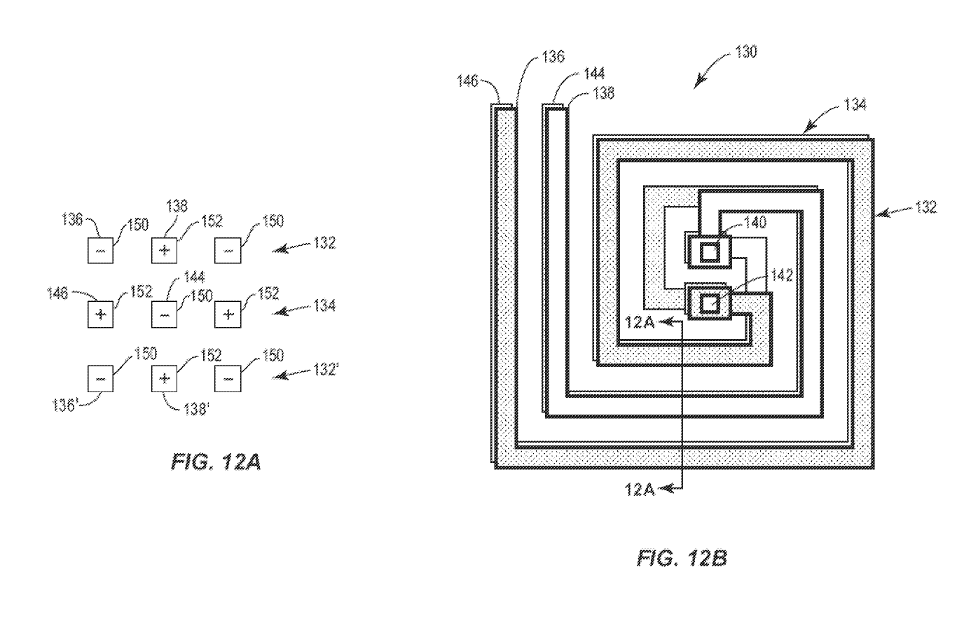

In this regard, FIG. 11 illustrates the layers 132, 134 from a top elevational view with the first trace 136 shaded the same as corresponding trace 144 and the second trace 138 shaded the same as corresponding trace 146 to highlight the commonality of the traces. In effect, this embodiment forms a first electrode 150 out of the first trace 136 and the corresponding trace 144 and a second electrode 152 out of the second trace 138 and the corresponding trace 146. The layers 132, 134 alternate which electrode is exteriorly positioned on the spiral. Note that while only two layers 132, 134 are illustrated, this pattern may be repeated through additional layers as better illustrated in FIG. 12A.

In this regard, FIG. 12A illustrates first layer 132 stacked on second layer 134, which in turn is stacked on layer 132′, which again reverses the arrangement of the traces such that the first electrode 150 is exteriorly positioned on the spiral relative to the second electrode 152. The stacking of layers provides additional capacitive density for the spiral MoM 130 by having more layers to have intralayer capacitance (e.g., between first trace 136 and second trace 138) and also creating interlayer capacitance between the layers 132, 134. FIG. 12B illustrates an assembled spiral MoM capacitor 130 with multiple layers 132, 134. However, as is readily apparent, the two dimensional foot print of the multilayer spiral MoM capacitor 130 is no larger than a single layer spiral MoM capacitor.

The SMoM capacitor according to embodiments disclosed herein may be provided in or integrated into any processor-based device. Examples, without limitation, include a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

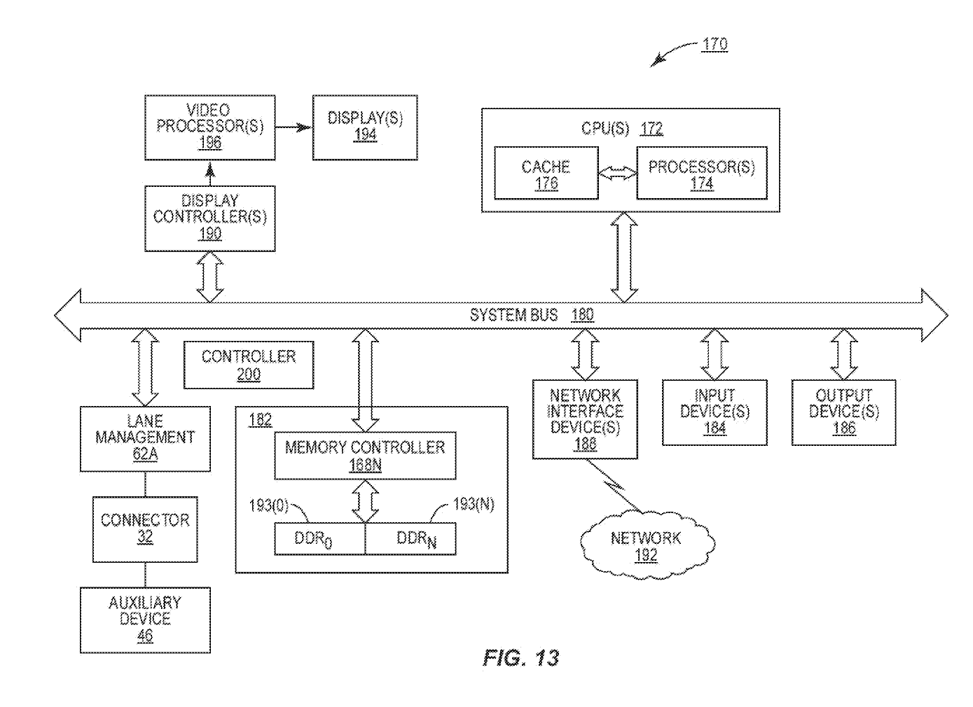

In this regard, FIG. 13 illustrates an example of a processor-based system 170 that can employ SMoM capacitors 50, 98, 110, or 130 illustrated in FIGS. 2, 8, 9, and 10-12B. In this example, the processor-based system 170 includes one or more central processing units (CPUs) 172, each including one or more processors 174. The CPU(s) 172 may have cache memory 176 coupled to the processor(s) 174 for rapid access to temporarily stored data. The CPU(s) 172 is coupled to a system bus 180 and can intercouple master devices and slave devices included in the processor-based system 170. As is well known, the CPU(s) 172 communicates with these other devices by exchanging address, control, and data information over the system bus 180. For example, the CPU(s) 172 can communicate bus transaction requests to the memory controller 168N as an example of a slave device. Although not illustrated in FIG. 13, multiple system buses 180 could be provided, wherein each system bus 180 constitutes a different fabric.

Other master and slave devices can be connected to the system bus 180. As illustrated in FIG. 13, these devices can include a memory system 182, one or more input devices 184, one or more output devices 186, one or more network interface devices 188, and one or more display controllers 190, as examples. The input device(s) 184 can include any type of input device, including but not limited to input keys, switches, voice processors, etc. The output device(s) 186 can include any type of output device, including but not limited to audio, video, other visual indicators, etc. The network interface device(s) 188 can be any devices configured to allow exchange of data to and from a network 192. The network 192 can be any type of network, including but not limited to a wired or wireless network, private or public network, a local area network (LAN), a wide local area network (WLAN), and the Internet. The network interface device(s) 188 can be configured to support any type of communication protocol desired. The memory system 182 can include one or more memory units 193(0-N).

The CPU 172 may also be configured to access the display controller(s) 190 over the system bus 180 to control information sent to one or more displays 194. The display controller(s) 190 sends information to the display(s) 194 to be displayed via one or more video processors 196, which process the information to be displayed into a format suitable for the display(s) 194. The display(s) 194 can include any type of display, including but not limited to a cathode ray tube (CRT), a liquid crystal display (LCD), a plasma display, etc.

The CPU(s) 172 and the display controller(s) 190 may act as master devices to make memory access requests over the system bus 180. Different threads within the CPU(s) 172 and the display controller(s) 190 may make requests.

Those of skill in the art would further appreciate that the various illustrative logical blocks, modules, circuits, and algorithms described in connection with the embodiments disclosed herein may be implemented as electronic hardware, instructions stored in memory or in another computer-readable medium and executed by a processor or other processing device, or combinations of both. The arbiters, master devices, and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present invention.

The various illustrative logical blocks, modules, and circuits described in connection with the embodiments disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The embodiments disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary embodiments herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary embodiments may be combined. It is to be understood that the operational steps illustrated in the flow chart diagrams may be subject to numerous different modifications as will be readily apparent to one of skill in the art. Those of skill in the art would also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A multilayer metal-on-metal (MoM) capacitor disposed in a semiconductor die, the multilayer MoM capacitor comprising:
a first layer comprising:
a first electrode of the MoM capacitor coupled to a first trace, the first trace coiled in a first inwardly spiraling pattern and comprised of first parallel trace segments; and
a second electrode of the MoM capacitor coupled to a second trace, the second trace coiled inside the first inwardly spiraling pattern and comprised of second parallel trace segments interdisposed between the first parallel trace segments; and
a second layer comprising:
the second electrode of the MoM capacitor coupled to a third trace, the third trace coiled in a second inwardly spiraling pattern; and
the first electrode of the MoM capacitor coupled to a fourth trace, the fourth trace coiled inside the second inwardly spiraling pattern.

2. The multilayer MoM capacitor of claim 1, wherein the second parallel trace segments are disposed substantially centered between the first parallel trace segments.

3. The multilayer MoM capacitor of claim 1, wherein the first and second parallel trace segments are substantially rectilinear.

4. The multilayer MoM capacitor of claim 1, wherein a spacing between the first parallel trace segments and the second parallel trace segments is less than approximately 40 nm.

5. The multilayer MOM capacitor of claim 1, further comprising a third layer comprising two inwardly spiraling conductive elements, a first inwardly spiraling conductive element electrically coupled to the first electrode and a second inwardly spiraling conductive element electrically coupled to the second electrode, wherein the first inwardly spiraling conductive element is exteriorly positioned relative to the second inwardly spiraling conductive element.

6. The multilayer MoM capacitor of claim 1, wherein the first trace and the fourth trace are coupled with a via positioned proximate a center of the first trace.

7. The multilayer MoM capacitor of claim 1 formed during a back end of line (BEOL) manufacturing process.

8. The multilayer MoM capacitor of claim 1, further comprising a device selected from the group consisting of: a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player, into which a MoM capacitor is integrated.

9. A multilayer metal-on-metal (MoM) capacitor disposed in a semiconductor die, the multilayer MoM capacitor comprising:
a first layer comprising:
a first electrode of the MoM capacitor coupled to a first conducting means, the first conducting means coiled in a first inwardly spiraling pattern and comprised of first parallel trace segments; and
a second electrode of the MoM capacitor coupled to a second conducting means, the second conducting means coiled inside the first inwardly spiraling pattern and comprised of second parallel trace segments interdisposed between the first parallel trace segments; and
a second layer comprising:
the second electrode of the MoM capacitor coupled to a third conducting means, the third conducting means coiled in a second inwardly spiraling pattern; and
the first electrode of the MoM capacitor coupled to a fourth conducting means, the fourth conducting means coiled inside the second inwardly spiraling pattern.

10. The multilayer MoM capacitor of claim 9 wherein the first conducting means comprises a first trace.

11. The multilayer MoM capacitor of claim 9 wherein the second conducting means comprises a second trace.

12. A circuit in a semiconductor die comprising a multilayer MoM capacitor, the multilayer MoM capacitor comprising:
a first layer comprising:
a first electrode of the MoM capacitor coupled to a first trace, the first trace coiled in a first inwardly spiraling pattern and comprised of first parallel trace segments; and
a second electrode of the MoM capacitor coupled to a second trace, the second trace coiled inside the first inwardly spiraling pattern and comprised of second parallel trace segments interdisposed between the first parallel trace segments; and
a second layer comprising:
the second electrode of the MoM capacitor coupled to a third trace, third trace coiled in a second inwardly spiraling pattern; and
the first electrode of the MoM capacitor coupled to a fourth trace, the fourth trace coiled inside the second inwardly spiraling pattern.

13. A method of forming a metal-on-metal (MoM) capacitor comprising:
providing a first mask for a semiconductor die, the first mask delimiting a first inwardly spiraling pattern;
positioning the first mask on a top layer of the semiconductor die;
depositing a first metal on the first mask to form a first electrode and a first trace of the MoM capacitor, the first trace formed in the inwardly spiraling pattern comprised of first parallel trace segments;
providing a second mask for the semiconductor die, the second mask delimiting a second inwardly spiraling pattern;
positioning the second mask on the top layer of the semiconductor die;
depositing a second metal on the second mask to form a second electrode and a second trace of the MoM capacitor, the second trace formed coiled in the first inwardly spiraling pattern and comprised of second parallel trace segments interdisposed between the first parallel trace segments.

14. The method of claim 13, wherein the first and second metals are the same and are conductive metals.

15. The method of claim 13, further comprising removing the first mask prior to positioning the second mask.

16. The method of claim 13, wherein depositing the second metal to form the second electrode and the second trace comprises disposing the second parallel trace segments substantially centered between the first parallel trace segments.

17. The method of claim 13, wherein providing the first mask comprises providing a first mask with a first substantially rectilinear inwardly spiraling pattern.

18. The method of claim 13, wherein a spacing between parallel trace segments is less than approximately 40 nm.

19. The method of claim 13, further comprising assembling a second layer of the MoM capacitor positioned above a plane defined by the first and second electrode.

20. The method of claim 19, wherein assembling the second layer comprises positioning spiral elements within one another in such a manner that elements electrically coupled to the first trace are inwardly positioned relative to elements electrically coupled to the second trace.
